(19) United States
(12) Patent Application Publication
(10) Pub. No.: US 2019/0102596 A1
(43) Pub. Date: Apr. 4, 2019

(54) DETECTION DEVICE AND ELECTRONIC APPARATUS

(71) Applicant: Japan Display Inc., Tokyo (JP)

(72) Inventors: Daichi SUZUKI, Tokyo (JP); Hayato KURASAWA, Tokyo (JP); Hiroshi MIZUHASHI, Tokyo (JP); Toshinori UEHARA, Tokyo (JP); Yuji SUZUKI, Tokyo (JP)

(21) Appl. No.: 16/142,359

(22) Filed: Sep. 26, 2018

(30) Foreign Application Priority Data
Sep. 29, 2017 (JP) 2017-191882

(51) Int. Cl. G06K 9/00; H01L 23/00; H01L 23/31; H01L 23/498

(52) U.S. Cl. CPC G06K 9/0004; H01L 24/48; H01L 23/3121; H01L 23/49833; H01L 23/4985; H01L 27/1214; H01L 24/32; H01L 24/73; H01L 2224/32225; H01L 2224/73265; H01L 2224/48227; H01L 2224/48106

(57) ABSTRACT

According to an aspect, a detection device includes: a first circuit substrate; a glass substrate attached at a position close to one surface of the first circuit substrate; a metal wire that couples an electrode provided on the one surface of the first circuit substrate to an electrode provided on the glass substrate; and a resin member that covers the glass substrate and the metal wire. The glass substrate includes a detection electrode that detects electrostatic capacitance.

### CROSS-REFERENCE TO RELATED APPLICATIONS

This application claims priority from Japanese Application No. 2017-191882, filed on Sep. 29, 2017, the contents of which are incorporated by reference herein in its entirety.

### BACKGROUND

### 1. Technical Field

The present disclosure relates to a detection device and an electronic apparatus.

### 2. Description of the Related Art

Japanese Patent Application Laid-open No. 2004-317353, for example, discloses a known detection device of an electrostatic capacitance type that detects a shape of a finger print by detecting ridges and valleys of a surface of a finger.

The electrostatic capacitance type detection device has been demanded to increase its detection sensitivity.

### SUMMARY

According to an aspect, a detection device includes: a first circuit substrate; a glass substrate attached at a position close to one surface of the first circuit substrate; a metal wire that couples an electrode provided on the one surface of the first circuit substrate to an electrode provided on the glass substrate; and a resin member that covers the glass substrate and the metal wire. The glass substrate includes a detection electrode that detects electrostatic capacitance.

### BRIEF DESCRIPTION OF THE DRAWINGS

FIG. 1 is a perspective view illustrating an exemplary configuration of a detection device according to a first embodiment;

FIG. 2 is a plan view illustrating the exemplary configuration of the detection device according to the first embodiment;

FIG. 3 is a cross-sectional view along line A11-A12 in the plan view illustrated in FIG. 2;

FIG. 4 is a cross-sectional view along line A13-A14 in the plan view illustrated in FIG. 2;

FIG. 5 is a plan view illustrating an exemplary configuration of a detection element according to the first embodiment;

FIG. 6 is a cross-sectional view illustrating the exemplary configuration of the detection element according to the first embodiment;

FIG. 7 is a cross-sectional view illustrating an exemplary configuration of a glass substrate;

FIG. 8 is a block diagram illustrating an exemplary configuration of a finger print detection device including a finger print sensor;

FIG. 9 is a plan view illustrating the exemplary configuration of a finger print sensor;

FIG. 10 is a diagram for explaining the basic principle of mutual capacitance detection;

FIG. 11 is a diagram illustrating an exemplary equivalent circuit for explaining the basic principle of the mutual capacitance detection;

FIG. 12 is a schematic diagram illustrating exemplary waveforms of a drive signal and a detection signal in the mutual capacitance detection;

FIG. 13 is a diagram schematically illustrating a state where an alternating current (AC) rectangular wave voltage from a transmission conductor has an influence on detection electrodes via a finger;

FIG. 14 is a cross-sectional view illustrating a manufacturing method of the detection device according to the first embodiment;

FIG. 15 is another cross-sectional view illustrating the configuration of the detection device according to the first embodiment;

FIG. 16 is another cross-sectional view illustrating the configuration of the detection device according to the first embodiment;

FIG. 17 is another cross-sectional view illustrating the manufacturing method of the detection device according to the first embodiment;

FIG. 18 is another cross-sectional view illustrating the manufacturing method of the detection device according to the first embodiment;

FIG. 19 is another cross-sectional view illustrating the manufacturing method of the detection device according to the first embodiment;

FIG. 20 is another cross-sectional view illustrating the manufacturing method of the detection device according to the first embodiment;

FIG. 21 is another cross-sectional view illustrating the manufacturing method of the detection device according to the first embodiment;

FIG. 22 is a cross-sectional view illustrating a state where a metal wire is in contact with the glass substrate in the detection element according to the first embodiment;

FIG. 23 is a cross-sectional view illustrating an exemplary configuration of the detection element according to a comparative example;

FIG. 24 is a cross-sectional view illustrating an exemplary configuration of a detection device according to a second embodiment;

FIG. 25 is a schematic diagram illustrating an exemplary configuration of an electronic apparatus with a detection function according to a third embodiment.

### DETAILED DESCRIPTION

Exemplary aspects (embodiments) according to the present disclosure are described below in greater detail with reference to the accompanying drawings. The contents described in the embodiments are not intended to limit the present disclosure. Components described below include components easily conceivable by those skilled in the art and components substantially identical therewith. Furthermore, the components described below can be appropriately combined. The disclosure is given by way of example only, and various changes made without departing from the spirit of the disclosure and easily conceivable by those skilled in the art are naturally included in the scope of the disclosure. The drawings may possibly illustrate the width, the thickness, the shape, and the like of each unit more schematically than the actual aspect to simplify the explanation. These elements, however, are given by way of example only and are not intended to limit interpretation of the present disclosure. In the specification and the drawings, components similar to those previously described with reference to a preceding drawing are denoted by like reference numerals, and detailed explanation thereof will be appropriately omitted. In this disclosure, when an element A is described as being “on” another element B, the element A can be directly on the other element B, or there can be one or more elements between the element A and the other element B.

### First Embodiment

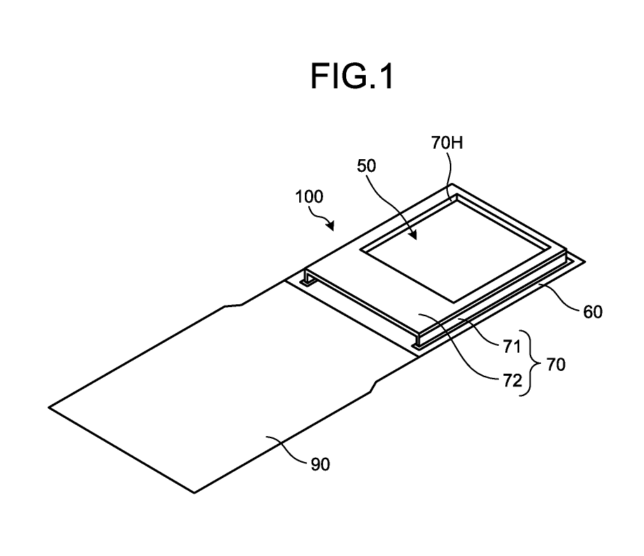

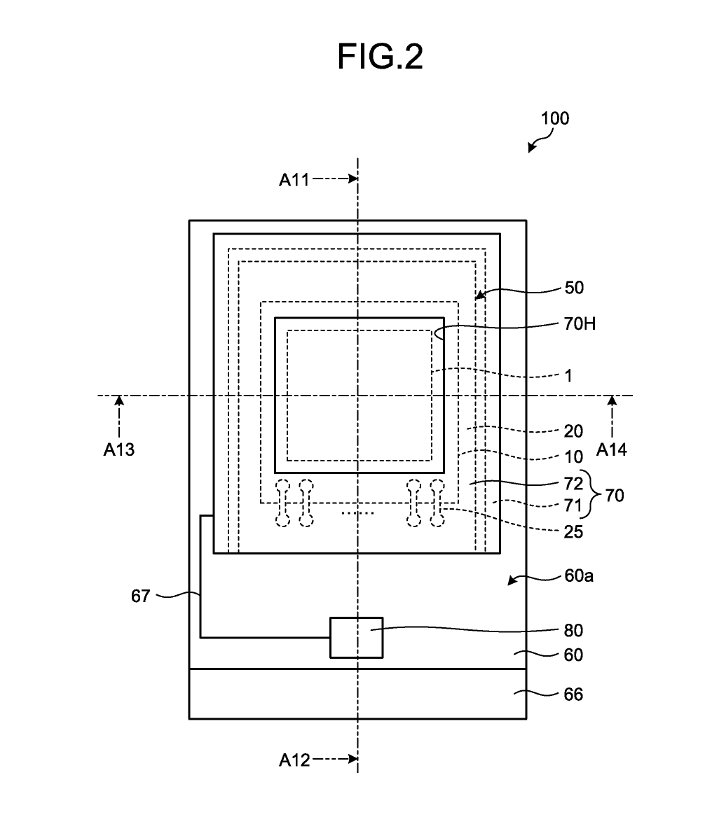

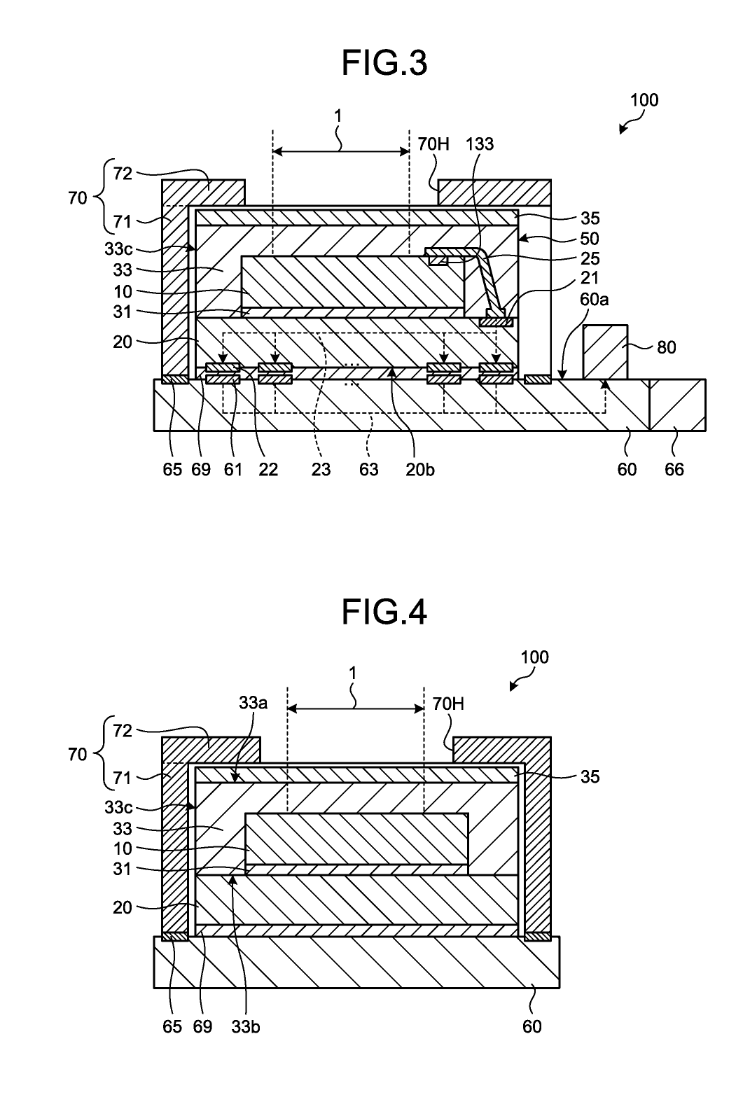

FIG. 1 is a perspective view illustrating an exemplary configuration of a detection device according to a first embodiment. FIG. 2 is a plan view illustrating the exemplary configuration of the detection device according to the first embodiment. FIG. 3 is a cross-sectional view along line A11-A12 in the plan view illustrated in FIG. 2. FIG. 4 is a cross-sectional view along line A13-A14 in the plan view illustrated in FIG. 2.

FIG. 2 illustrates a finger print sensor 1, a glass substrate 10, a first circuit substrate 20, metal wires 25, a coating layer 35, a second circuit substrate 60, a surface 60a, which is one surface of the second circuit substrate 60, a second terminal 65, an external coupling terminal 66, second wiring 67, a transmission conductor 70, a through-hole 70H, and an integrated circuit (IC) element 80, which are included in a detection device 100.

FIG. 3 illustrates the finger print sensor 1, the glass substrate 10, the first circuit substrate 20, a lower surface 20b, a pad electrode 21, a coupling terminal 22, wiring 23, a resin member 33, a side surface 33c of the resin member 33, the coating layer 35, the second circuit substrate 60, an upper surface 60a of the second circuit substrate 60, a first terminal 61, first wiring 63, the second terminal 65, an adhesive layer 69, the transmission conductor 70, the through-hole 70H, a first portion 71 and a second portion 72 of the transmission conductor 70, and a pad electrode 133, which are included in the detection device 100.

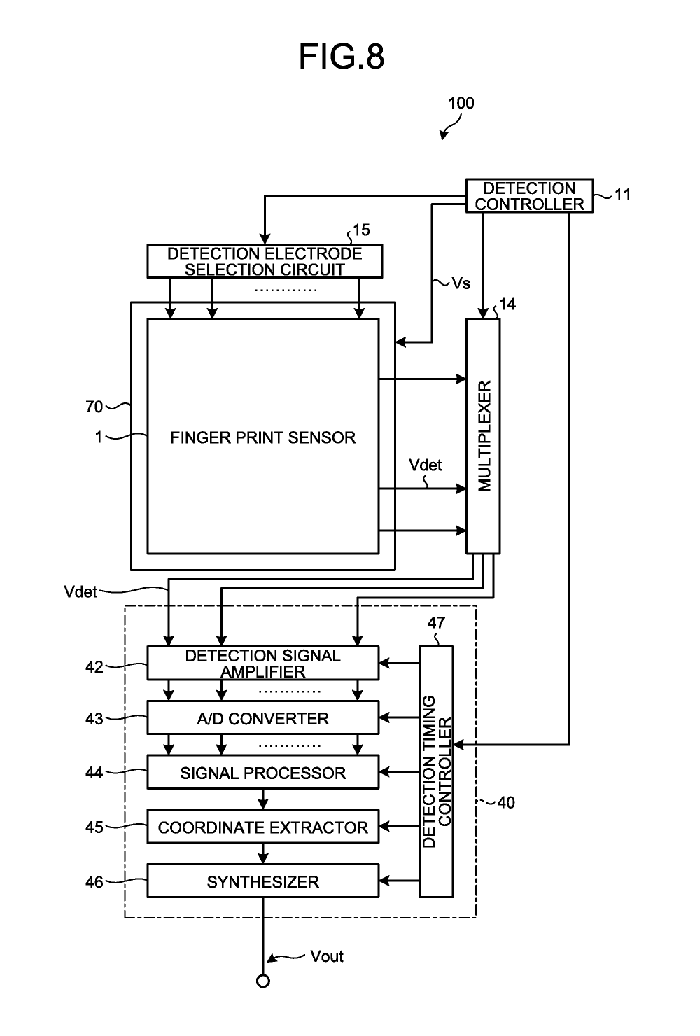

As illustrated in FIGS. 1 to 4, the detection device 100 includes the second circuit substrate 60, a detection element 50, the adhesive layer 69, the transmission conductor 70, and the IC element 80. The detection element 50 is positioned close to the surface 60a (hereinafter referred to as the upper surface), which is one surface of the second circuit substrate 60. The adhesive layer 69 is disposed between the second circuit substrate 60 and the detection element 50. The transmission conductor 70 is positioned close to the upper surface 60a of the second circuit substrate 60. The IC element 80 is positioned close to the upper surface 60a. The adhesive layer 69 is an anisotropic conductive film (ACF), for example. The IC element 80 functions as a detector 40 (refer to FIG. 8), which is described later.

The second circuit substrate 60 is a flexible printed circuit (FPC) substrate, for example. The second circuit substrate 60 employs a thin insulating film base material having high flexibility. The second circuit substrate 60 includes the first terminal 61, the second terminal 65, the first wiring 63, and the second wiring 67. The first wiring 63 couples the first terminal 61 to the IC element 80. The second wiring 67 couples the second terminal 65 to the IC element 80. The first terminal 61 and the second terminal 65 are exposed on the upper surface 60a of the second circuit substrate 60. The first wiring 63 and the second wiring 67 are provided inside the second circuit substrate 60. The second circuit substrate 60 includes the external coupling terminal 66 that exchanges a signal with a device disposed outside the detection device 100.

As illustrated in FIG. 1, the detection device 100 may include a third circuit substrate 90. The third circuit substrate 90, which is an FPC substrate, for example, is coupled to the external coupling terminal 66 of the second circuit substrate 60.

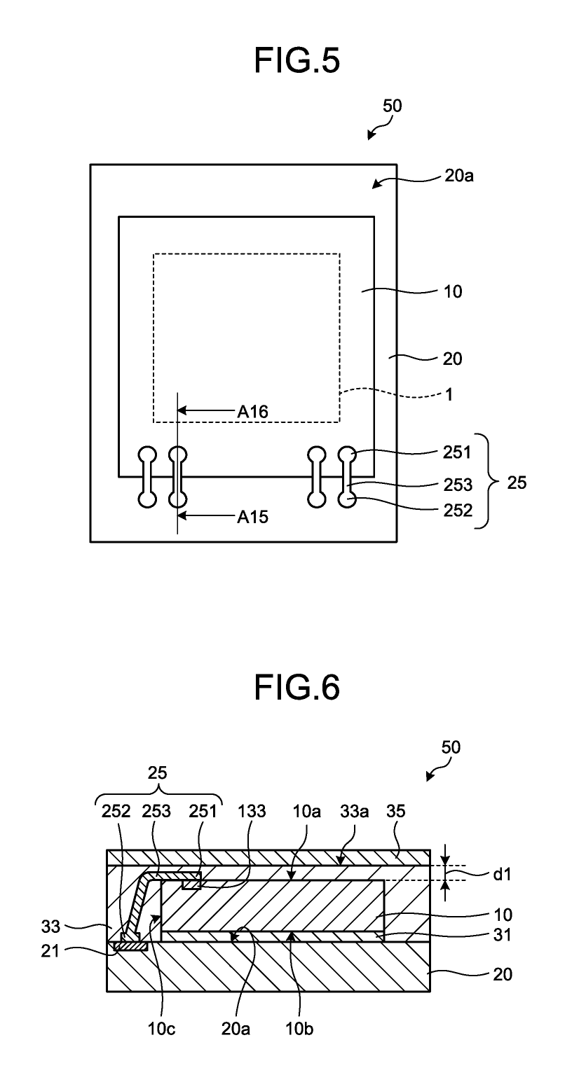

FIG. 5 is a plan view illustrating an exemplary configuration of the detection element according to the first embodiment. In FIG. 5, the coating layer and the resin member, which are described later, are omitted. FIG. 6 is a cross-sectional view illustrating the exemplary configuration of the detection element according to the first embodiment. The cross-sectional view illustrated in FIG. 6 includes a section along line A15-A16 in the plan view illustrated in FIG. 5.

As illustrated in FIGS. 5 and 6, the detection element 50 is a device including the finger print sensor 1. The detection element 50 includes the first circuit substrate 20, the glass substrate 10, an adhesive layer 31, the metal wires 25, the resin member 33, and the insulating coating layer 35. The glass substrate 10 is provided above a surface 20a (hereinafter referred to as the upper surface 20a) of the first circuit substrate 20. The adhesive layer 31 is disposed between the glass substrate 10 and the first circuit substrate 20. The metal wires 25 each couple the pad electrode 133 provided on the glass substrate 10 to the corresponding pad electrode 21 provided on the first circuit substrate 20. The resin member 33 is positioned close to the upper surface 20a of the first circuit substrate 20 and covers the glass substrate 10 and the metal wires 25. The insulating coating layer 35 is provided on an upper surface 33a of the resin member 33.

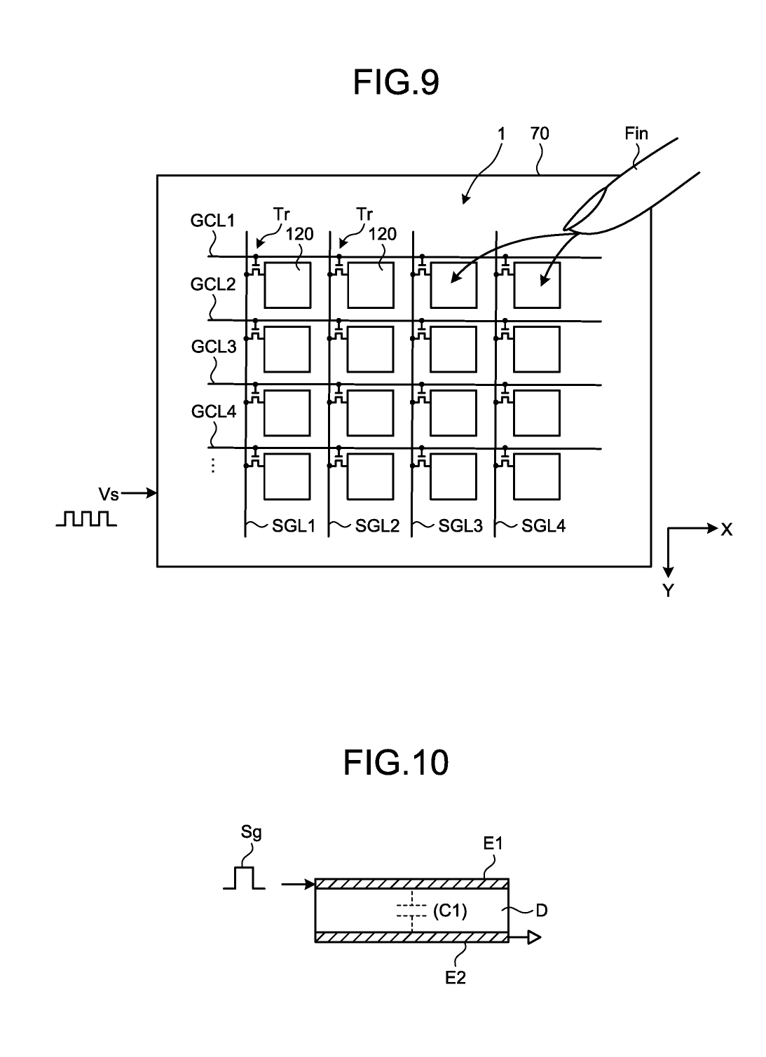

The glass substrate 10 has a lower surface 10b facing the first circuit substrate 20, an upper surface 10a on the opposite side of the lower surface 10b, and a side surface 10c between the upper surface 10a and the lower surface 10b. The glass substrate 10 is provided with the finger print sensor 1. The finger print sensor 1 is described later with reference to FIGS. 8 and 9. The first embodiment can employ an insulating substrate having a visible light transmittance that is equal to or larger than 70%, instead of the glass substrate.

The first circuit substrate 20 is a rigid substrate such as a printed circuit board (PCB), for example. The first circuit substrate 20 employs an insulating base material having a larger thickness and higher stiffness than those of the second circuit substrate 60. As illustrated in FIG. 3, the first circuit substrate 20 includes: the pad electrode 21 exposed on the upper surface 20a; the coupling terminal 22 exposed on the lower surface 20b; and the wire 23 that couples the coupling terminal 22 to the corresponding pad electrode 21. The wiring 23 is routed inside the insulating base material and couples the coupling terminal 22 to the corresponding pad electrode 21. The coupling terminal 22 is coupled to the first terminal 61 of the second circuit substrate 60 via the adhesive layer 69 such as the ACF. The pad electrode 21, the coupling terminal 22, and the wiring 23 are made of a metal such as copper (Cu), for example.

The adhesive layer 31 adhesively bonds the lower surface 10b of the glass substrate 10 to the upper surface 20a of the first circuit substrate 20. The adhesive layer 31 has an insulating property, for example. For the adhesive layer 31, a die attachment film (DAF) is used, for example. The DAF has a function as a dicing tape used in a dicing process, which is described later, and another function as an adhesive layer used in a die attachment process, which is described later. The DAF has a film and an adhesive layer provided on one surface of the film, which are not illustrated. The adhesive layer of the DAF is used for the adhesive layer 31.

The metal wire 25 has a first end portion 251, a second end portion 252, and a wire body 253. The first end portion 251 is coupled to the pad electrode 133 on the glass substrate 10. The second end portion 252 is coupled to the pad electrode 21 on the first circuit substrate 20. The wire body 253 is between the first end portion 251 and the second end portion 252. With this configuration, the metal wire 25 couples the pad electrode 133 on the glass substrate 10 to the pad electrode 21 on the first circuit substrate 20. The metal wire 25 is a gold (Au) wire, for example.

In the detection element 50 in the first embodiment, no current flows between the wire bodies 253 and the glass substrate 10. With this configuration, the wire bodies 253 of the metal wires 25 can be provided so as to be in contact with the glass substrate 10. In the example illustrated in FIG. 6, the wire body 253 can be disposed along the upper surface 10a and the side surface 10c of the glass substrate 10.

The resin member 33 is a thermoset resin composed mostly of an epoxy resin, for example. The resin member 33 is formed in a rectangular parallelepiped shape, for example. The resin member 33 covers and seals the glass substrate 10, the metal wires 25, and a region exposed from the adhesive layer 31 on the upper surface 20a of the first circuit substrate 20. A lower surface 33b (refer to FIG. 4) of the resin member 33 is in close contact with the first circuit substrate 20.

As illustrated in FIGS. 2 to 4, the transmission conductor 70 includes: the first portion 71 adjacent to the side surface 33c of the resin member 33; and the second portion 72 that is supported by the first portion 71 and covers the upper surface 33a of the resin member 33. The first portion 71 and the second portion 72 each have a plate-like shape. The end portion of the first portion 71 is coupled to the second terminal 65 exposed on the second circuit substrate 60 with solder (not illustrated), for example, interposed therebetween. The through-hole 70H is provided in the second portion 72 at a position facing the glass substrate 10. The second portion 72 has a ring shape surrounding the through-hole 70H. The transmission conductor 70 is a metal member made of a stainless steel, for example.

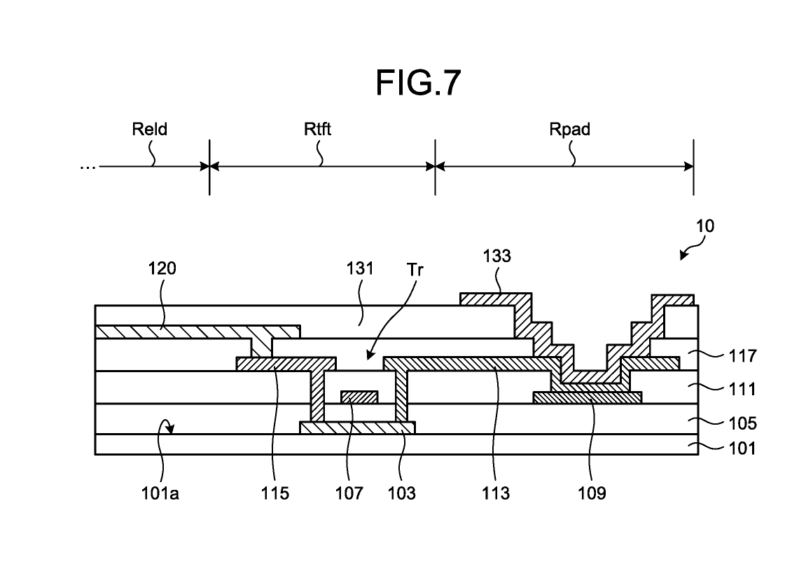

FIG. 7 is a cross-sectional view illustrating an exemplary configuration of the glass substrate. As illustrated in FIG. 7, the glass substrate 10 includes a base material 101 made of glass, a semiconductor layer 103, a first interlayer insulating film 105, a gate electrode 107, a wiring layer 109, a second interlayer insulating film 111, a source electrode 113, a drain electrode 115, a third interlayer insulating film 117, a detection electrode 120, a passivation film 131, and the pad electrode 133.

As illustrated in FIG. 7, the glass substrate 10 includes: a pad region Rpad in which the pad electrode 133 is disposed; a transistor region Rtft in which a thin film transistor Tr is disposed; and a detection region Reld in which the detection electrode 120 is disposed.

The semiconductor layer 103 is provided on a surface 101a, which is one surface of the base material 101, in the transistor region Rtft. The first interlayer insulating film 105, which is provided on the base material 101, covers the semiconductor layer 103. The upper surface of the first interlayer insulating film 105 is planarized.

The gate electrode 107 is provided on the first interlayer insulating film 105 in the transistor region Rtft. The wiring layer 109 is provided on the first interlayer insulating film 105 beneath the pad electrode 133. The second interlayer insulating film 111, which is provided on the first interlayer insulating film 105, covers the gate electrode 107 and the wiring layer 109. The upper surface of the second interlayer insulating film 111 is planarized.

In the transistor region Rtft, the second interlayer insulating film 111 and the first interlayer insulating film 105 have through-holes formed to reach the semiconductor layer 103 serving as bottom surfaces of the through-holes. In the pad region Rpad, the second interlayer insulating film 111 has a through-hole formed to reach the wiring layer 109 serving as a bottom surface of the through-hole. The source electrode 113 and the drain electrode 115 are formed on the second interlayer insulating film 111. In the transistor region Rtft, the source electrode 113 and the drain electrode 115 plug the through-holes in the second interlayer insulating film 111 and the first interlayer insulating film 105. With this configuration, the source electrode 113 and the drain electrode 115 are each coupled to the semiconductor layer 103. In the pad region Rpad, the source electrode 113 plugs the through-hole provided in the second interlayer insulating film 111. With this configuration, the source electrode 113 is coupled to the wiring layer 109.

The third interlayer insulating film 117, which is provided on the second interlayer insulating film 111, covers the source electrode 113 and the drain electrode 115. The upper surface of the third interlayer insulating film 117 is planarized. In the transistor region Rtft, the third interlayer insulating film 117 has a through-hole formed to reach the drain electrode 115 serving as a bottom surface of the though-hole. In the pad region Rpad, the third interlayer insulating film 117 has a through-hole formed to reach the source electrode 113 serving as a bottom surface of the through-hole. The detection electrode 120 is formed on the third interlayer insulating film 117. In the transistor region Rtft, the detection electrode 120 plugs the through-hole provided in the third interlayer insulating film 117. With this configuration, the detection electrode 120 is coupled to the drain electrode 115.

The passivation film 131, which is provided on the third interlayer insulating film 117, covers the detection electrode 120. In the pad region Rpad, the passivation film 131 and the third interlayer insulating film 117 have a through-hole formed to reach the source electrode 113 serving as a bottom surface of the through-hole. The pad electrode 133 is provided on the passivation film 131. In the pad region Rpad, the pad electrode 133 plugs the through-hole provided in the passivation film 131 and the third interlayer insulating film 117. With this configuration, the pad electrode 133 is coupled to the source electrode 113.

The following describes examples of materials used for the respective films layered on the base material 101. The first interlayer insulating film 105 is made of a silicon oxide film, a silicon nitride film, or a silicon oxide nitride film. The first interlayer insulating film 105 is not limited to a single layer film, and may be a multilayered film. The first interlayer insulating film 105 may be a multilayered film composed of a silicon oxide film and a silicon nitride film formed on the silicon oxide film. In the same manner as the first interlayer insulating film 105, each of the second interlayer insulating film 111 and the third interlayer insulating film 117 is also made of a silicon oxide film, a silicon nitride film, or a silicon oxide nitride film. Each of the second interlayer insulating film 111 and the third interlayer insulating film 117 is not limited to a single layer film, and may be a multilayered film.

The semiconductor layer 103 is made of a polysilicon film or an oxide semiconductor film. The gate electrode 107 and the wiring layer 109 are made of aluminum (Al), copper (Cu), silver (Ag), molybdenum (Mo), or an alloy thereof. The source electrode 113 and the drain electrode 115 are made of a titanium aluminum (TiAl) film. TiAl is an alloy of titanium and aluminum. The detection electrode 120 is made of a conductive film capable of transmitting visible light. Hereinafter, the property of capability of transmitting visible light is referred to as a light transmitting property. Examples of conductive film having light transmitting property include, but are not limited to, an indium tin oxide (ITO) film. The pad electrode 133 is made of an aluminum film or an aluminum alloy film. The passivation film 131, which is an insulating film, is a film made of an inorganic material such as silicon nitride, or a resin film.

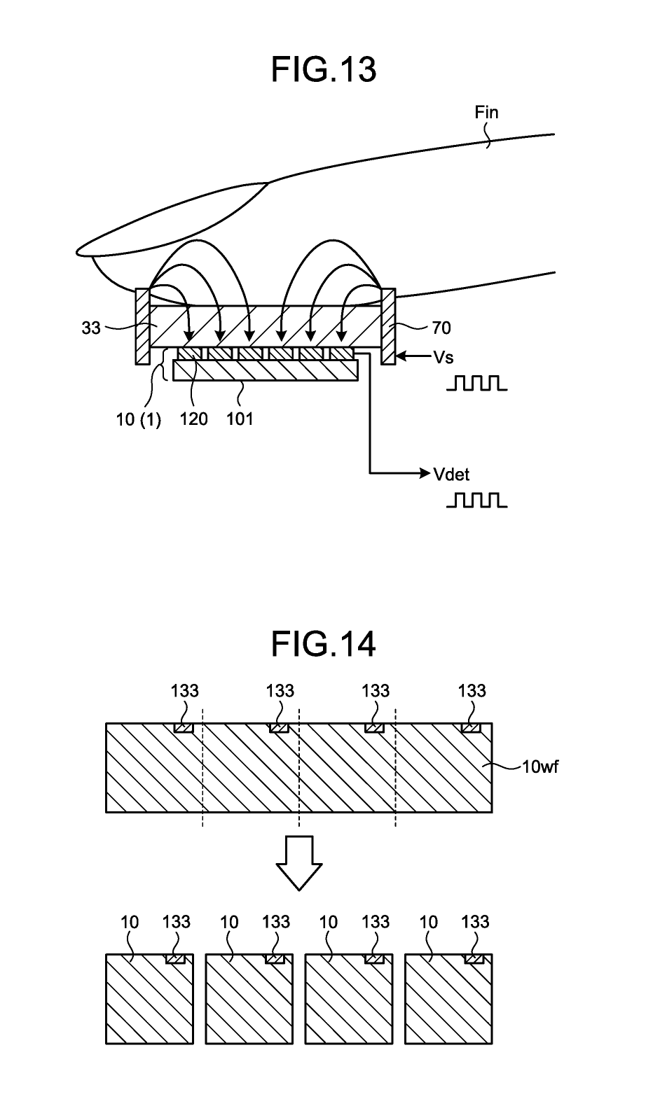

FIG. 8 is a block diagram illustrating an exemplary configuration of a finger print detection device including the finger print sensor. FIG. 9 is a plan view illustrating an exemplary configuration of the finger print sensor. As illustrated in FIG. 8, the detection device 100 includes the finger print sensor 1, a detection controller 11, a detection electrode selection circuit 15, a multiplexer 14, and the detector 40. The finger print sensor 1 is provided on the glass substrate 10 (refer to FIG. 13, which is described later).

The detection controller 11 is a circuit that controls detection operation of the finger print sensor 1. The detection controller 11 supplies a drive signal Vs for detection to the transmission conductor 70. The detection electrode selection circuit 15 selects the detection electrode 120 (refer to FIG. 13, which is described later) and couples the selected detection electrode 120 to the multiplexer 14, in accordance with a control signal supplied from the detection controller 11. The multiplexer 14 selects a detection signal Vdet supplied from the detection electrode 120 in accordance with a control signal supplied from the detection controller 11, and outputs the selected detection signal Vdet to the detector 40.

As illustrated in FIG. 9, the finger print sensor 1 includes the detection electrodes 120, signal lines SGL1, SGL2, . . . , and gate lines GCL1, GCL2, . . . . The detection electrodes 120 are arranged in a matrix in a row direction (X-axis direction) and a column direction (Y-axis direction). The signal lines SGL1, SGL2, . . . are wiring that outputs the detection signals Vdet. The signal lines SGL1, SGL2, . . . are coupled to the respective source electrodes 113 (refer to FIG. 7) of the thin film transistors Tr. The signal lines SGL1, SGL2, . . . are arranged in the row direction (X-axis direction) and extend in the column direction (Y-axis direction). The gate lines GCL1, GCL2, . . . are wiring that turns on or off the thin film transistors Tr. The gate line lines GCL 1, GCL2, . . . are coupled to the respective gate electrodes 107 (refer to FIG. 7) of the thin film transistors Tr. The gate lines GCL1, GCL2, . . . are arranged in the column direction (Y-axis direction) and extend in the row direction (X-axis direction).

The detection electrode selection circuit 15 selects one gate line GCL (e.g., GCL2) out of the gate lines GCL1, GCL2, . . . , in accordance with the control signal supplied from the detection controller 11. The detection electrode selection circuit 15 applies a certain voltage to the selected gate line GCL2. As a result, the detection electrodes 120 in the second row are coupled to the multiplexer via the signal lines SGL1, SGL2, . . . . The multiplexer 14 selects one or more of the signal lines SGL (e.g., SGL2 and SGL 4) out of the signal lines SGL1, SGL2, in accordance with the control signal supplied from the detection controller 11. The multiplexer 14 couples the selected signal lines SGL2 and SGL4 to the detector 40. As a result, the detection signal Vdet is supplied to the detector 40 from the detection electrode 120 at the second row and the second column. Likewise, the detection signal Vdet is supplied to the detector 40 from the detection electrode 120 at the second row and the fourth column.

The detector 40 is a circuit that detects ridges and valleys of a surface of a finger or the like in contact with or in proximity to the finger print sensor 1, in accordance with a control signal supplied from the detection controller 11 and the detection signals Vdet output from the multiplexer 14 to detect the shape of a finger print and the finger print. The detector 40 includes a detection signal amplifier 42, an analog-digital (A/D) converter 43, a signal processor 44, a coordinate extractor 45, a synthesizer 46, and a detection timing controller 47. The detection timing controller 47 performs control such that the detection signal amplifier 42, the A/D converter 43, the signal processor 44, the coordinate extractor 45, and the synthesizer 46 operate in synchronization with one another, in accordance with the control signal supplied from the detection controller 11.

The detection signal Vdet is supplied from the finger print sensor 1 to the detection signal amplifier 42 of the detector 40. The detection signal amplifier 42 amplifies the detection signal Vdet. The A/D converter 43 converts an analog signal output from the detection signal amplifier 42 into a digital signal.

The signal processor 44 is a logic circuit that detects whether a finger is in contact with or in proximity to the finger print sensor 1, in accordance with a signal output from the A/D converter 43. The signal processor 44 performs processing for extracting a signal (absolute value |ΔV|) of a difference between the detection signals caused by the finger. The signal processor 44 compares the absolute value |ΔV| with a certain threshold voltage. When the absolute value |ΔV| is smaller than the threshold voltage, the signal processor 44 determines that the finger is not in contact with the finger print sensor 1, i.e., in a non-contact state. When the absolute value |ΔV| is equal to or larger than the threshold voltage, the signal processor 44 determines that the finger is in contact with or in proximity to the finger print sensor 1, i.e., in a contact or a proximity state. In this way, the detector 40 can detect the contact of the finger with or the proximity of the finger to the finger print sensor 1.

The coordinate extractor 45 is a logic circuit that, when the signal processor 44 detects the contact of or the proximity of the finger, obtains coordinates thereof. The coordinate extractor 45 outputs the detection coordinates to the synthesizer 46. The synthesizer 46 synthesizes the detection signals Vdet output from the finger print sensor 1 to generate two-dimensional information indicating the shape or the finger print of the finger that is in contact with or in proximity to the finger print sensor 1. The synthesizer 46 outputs the two-dimensional information as an output Vout of the detector 40. The synthesizer 46 may produce an image based on the two-dimensional information and output the image as the output Vout.

The IC element 80 (refer to FIG. 2) functions as the detector 40 illustrated in FIG. 8. A part of the functions of the detector 40 may be included in an IC element, which is not illustrated and mounted on the first circuit substrate 20 (refer to FIG. 2), or may be provided as the function of an external micro processing unit (MPU).

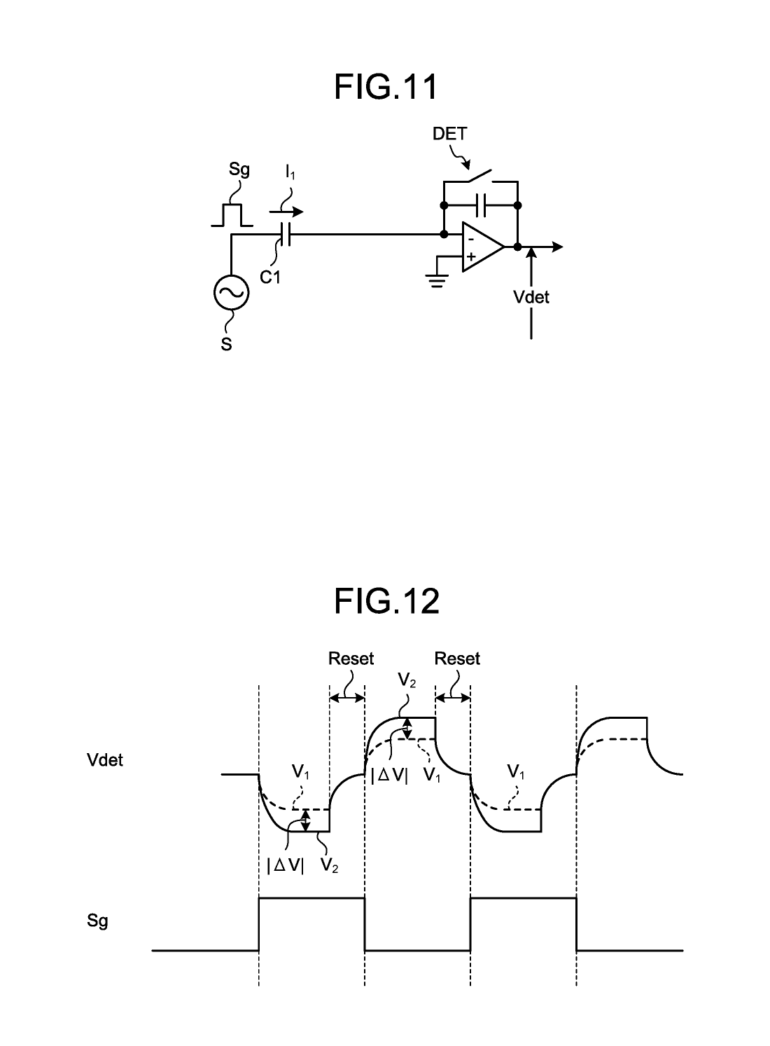

The finger print sensor 1 operates based on the basic principle of electrostatic capacitance detection. The following describes the basic principle of detection by the finger print sensor 1 with reference to FIGS. 10 to 13. FIG. 10 is a diagram for explaining the basic principle of mutual capacitance detection. FIG. 11 is a diagram illustrating an exemplary equivalent circuit for explaining the basic principle of the mutual capacitance detection. FIG. 12 is a schematic diagram illustrating exemplary waveforms of a drive signal and a detection signal in the mutual capacitance detection. FIG. 13 is a diagram schematically illustrating a state where an alternating current (AC) rectangular wave voltage from the transmission conductor has an influence on the detection electrodes via a finger. The drive electrode E1 illustrated in FIG. 10 corresponds to the transmission conductor 70 illustrated in FIG. 13. The drive electrode E2 illustrated in FIG. 10 corresponds to the detection electrode 120 illustrated in FIG. 13.

As exemplarily illustrated in FIG. 10, a capacitance element C1 includes the drive electrode E1 and the detection electrode E2, a pair of electrodes facing each other with a dielectric body D interposed therebetween. As illustrated in FIG. 11, one end of the capacitance element C1 is coupled to an AC signal source (drive signal source) S while the other end of the capacitance element C1 is coupled to a voltage detector DET. The voltage detector DET is an integration circuit included in the detector 40 illustrated in FIG. 8, for example.

When an AC rectangular wave Sg having a certain frequency (e.g., in a range from several KHz to several hundred KHz) is applied to the drive electrode E1 (the one end of the capacitance element C1) from the AC signal source S, an output waveform (the detection signal Vdet) as illustrated in FIG. 12 appears via the voltage detector DET coupled to the detection electrode E2 (the other end of the capacitance element C1). The AC rectangular wave Sg corresponds to the drive signal Vs output from the detection controller 11 illustrated in FIG. 8.

In a state where a finger is not in contact with or not in proximity to the finger print sensor 1 (in the non-contact state), current according to a capacitance value of the capacitance element C1 flows in accordance with charging and discharging of the capacitance element C1. The voltage detector DET illustrated in FIG. 11 converts a change in current I₁ according to the AC rectangular wave Sg into a change in voltage (waveform V₁ illustrated with the dotted line in FIG. 12).

In a state where a finger is in contact with or is in proximity to the finger print sensor 1 (in the contact state), a finger Fin is in contact with the transmission conductor 70 (corresponding to the drive electrode E1) as illustrated in FIG. 13. The drive signal Vs (corresponding to the AC rectangular wave Sg) supplied to the transmission conductor 70 from the detection controller 11 has an influence on the detection electrodes 120 (each corresponding to the detection electrode E2) via the finger Fin. The finger Fin acts as a part of the drive electrode E1. In the contact state, a distance between the drive electrode E1 and the detection electrode E2 substantially becomes small. The capacitance element C1 illustrated in FIG. 10 acts as a capacitance element having a capacitance value larger than that in the non-contact state. As illustrated in FIG. 12, the voltage detector DET converts a change in current I₁ according to the AC rectangular wave Sg into a change in voltage (the waveform V₂ illustrated with the solid line in FIG. 12).

In this case, the waveform V₂ has amplitude larger than that of the waveform V₁. With this mechanism, the absolute value |ΔV| of a difference in voltage between the waveform V₁ and the waveform V₂ changes in accordance with the influence of an external object such as a finger, which is in contact with or in proximity to the finger print sensor 1. The voltage detector DET preferably operates with a time period of Reset for resetting charging and discharging of the capacitor in synchronization with a frequency of the AC rectangular wave Sg by switching operation in the circuit, in order to accurately detect the absolute value |ΔV| of a difference in voltage between the waveform V₁ and the waveform V₂.

The detector 40 compares the absolute value |ΔV| with a certain threshold voltage. When the absolute value |ΔV| is smaller than the threshold voltage, the detector 40 determines that the finger is in the non-contact state. When the absolute value |ΔV| is equal to or larger than the threshold voltage, the detector 40 determines that the finger is in the contact state or in the proximity state. When the detector 40determines that the finger is in the contact state or in the proximity state, it detects a change in capacitance caused by ridges and valleys of the surface of the finger based on the absolute value |ΔV|.

The following describes a manufacturing method of the detection device according to the first embodiment. FIGS. 14 to 21 are cross-sectional views each illustrating the manufacturing method of the detection device according to the first embodiment. As illustrated in FIG. 14, a manufacturing device dices a glass wafer 10wf, on which the finger print sensors 1 (refer to FIG. 8) are multiple-imposed in a matrix (dicing process). As a result, a plurality of glass substrates 10 are produced from the single glass wafer 10wf.

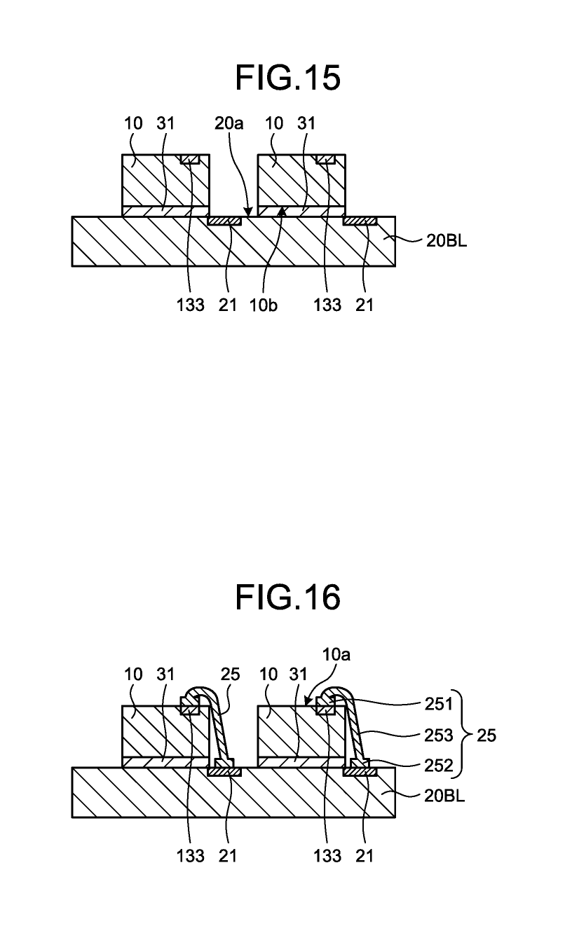

Subsequently, as illustrated in FIG. 15, the manufacturing device attaches the lower surface 10b of the glass substrate 10 to the upper surface 20a of a substrate 20BL with the adhesive layer 31 interposed therebetween (die attachment process). The first circuit substrates 20, one of which is illustrated in FIG. 6, are multiple-imposed in a matrix on the substrate 20BL. When an adhesive layer of a DAF is used for the adhesive layer 31, the manufacturing device may attach the DAF to the glass wafer 10wf prior to the dicing process. In this case, the manufacturing device may dice the adhesive layer of the DAF together with the glass wafer 10wf in the dicing process. This makes it easier to provide the adhesive layers 31 than a case where the adhesive layers 31 are individually applied to (or pasted on) the glass substrates 10 after the dicing process.

Subsequently, as illustrated in FIG. 16, the manufacturing device couples the respective pad electrodes 133 provided on the glass substrate 10 to the respective pad electrodes 21 provided on the substrate 20BL with the metal wires 25 (wire bonding process). In the wire bonding process, the first end portion 251 of the metal wire 25 is coupled to the pad electrode 133 provided on the glass substrate 10. The second end portion 252 of the metal wire 25 is coupled to the corresponding pad electrode 21 provided on the substrate 20BL.

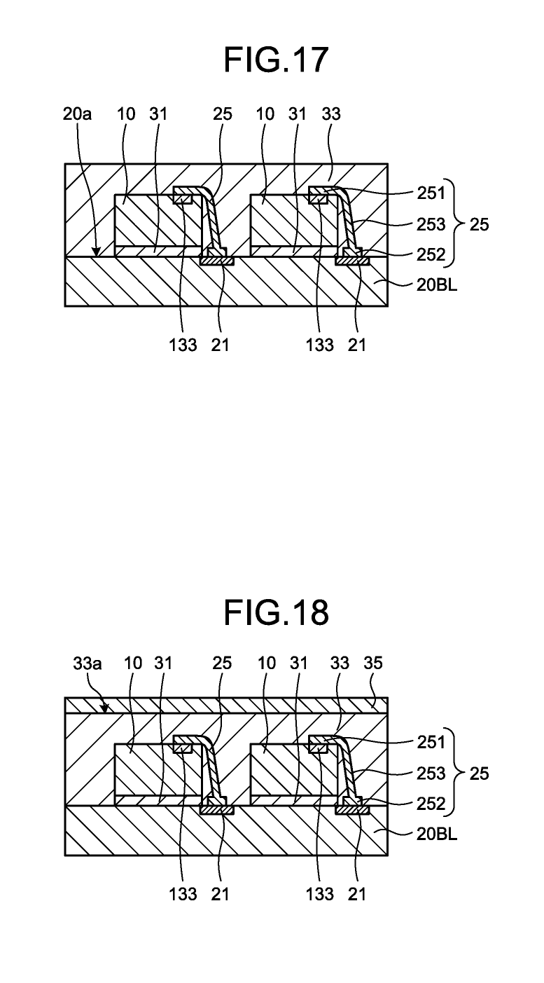

As illustrated in FIG. 17, the manufacturing device seals the glass substrate 10 attached to the substrate 20BL and the metal wires 25 with the resin member 33 (molding process). In the molding process, a molding die (not illustrated) is provided to the substrate 20BL on the side to which the glass substrate 10 is attached. The manufacturing device injects a resin into a space sandwiched between the molding die and the substrate 20BL. This process forms the resin member 33 that seals the glass substrate 10 and the metal wires 25.

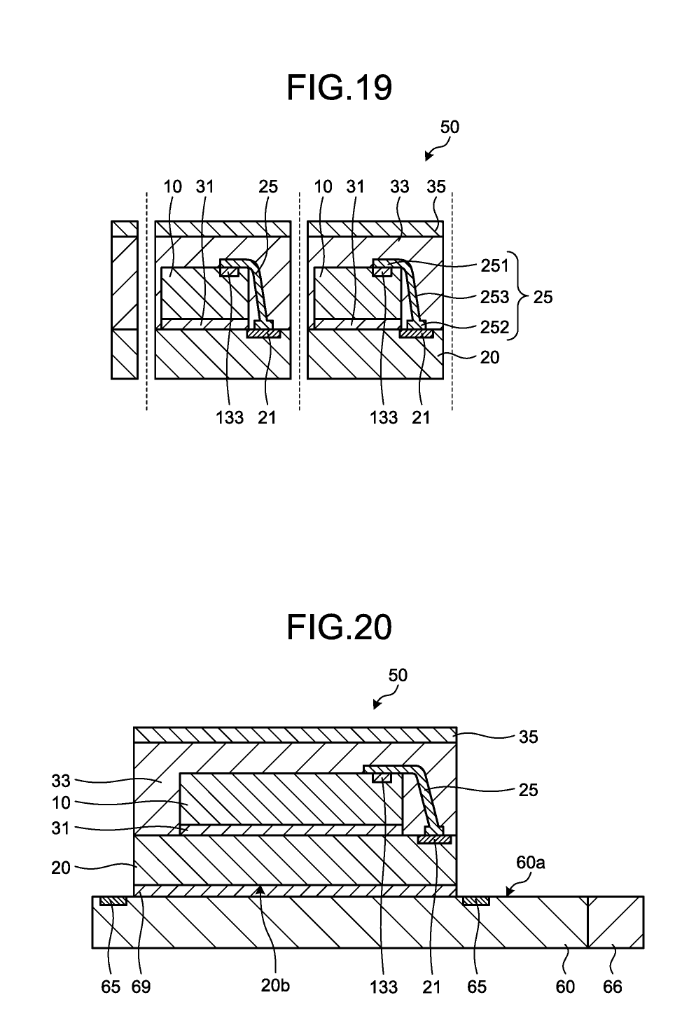

As illustrated in FIG. 18, the manufacturing device applies an insulating resin onto the upper surface 33a of the resin member 33 to form the coating layer 35 (coating process). Subsequently, as illustrated in FIG. 19, the manufacturing device dices the coating layer 35, the resin member 33, and the substrate 20BL (refer to FIG. 18) for singulation (singulation process). This process produces a plurality of detection elements 50.

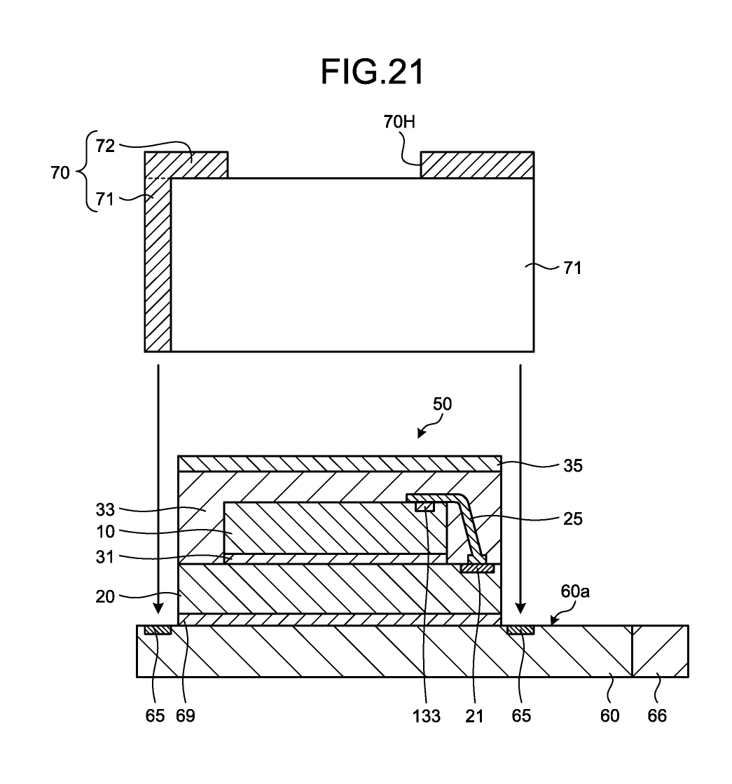

Subsequently, as illustrated in FIG. 20, the manufacturing device attaches the detection element 50 to the upper surface 60a of the second circuit substrate 60 with the adhesive layer 69 interposed therebetween (substrate attachment process). As illustrated in FIG. 21, before or after the substrate attachment process, the manufacturing device attaches the transmission conductor 70 to the upper surface 60a of the second circuit substrate 60 (transmission conductor attachment process). Accordingly, the second portion 72 in a ring shape of the transmission conductor 70 is supported by the first portion 71 above the second circuit substrate 60. The upper surface of the detection element 50 faces the second portion 72 in the ring shape. The three side surfaces out of the four side surfaces of the detection element 50 face the first portion 71 having a wall shape. In the transmission conductor attachment process, the end portion of the first portion 71 of the transmission conductor 70 is coupled to the second terminal 65 of the second circuit substrate 60 with solder (not illustrated), for example, interposed therebetween. As a result of the processes described above, the detection device 100, which is illustrated in FIGS. 1 to 4, is completed.

As described above, the detection device 100 according to the first embodiment includes the detection element 50. The detection element 50 includes the first circuit substrate 20, the glass substrate 10, the metal wires 25, and the resin member 33. The glass substrate 10 is attached to the first circuit substrate 20. The metal wires 25 each couple the pad electrode 21 provided on the first circuit substrate 20 to the corresponding pad electrode 133 provided on the glass substrate 10. The resin member 33 covers the glass substrate 10 and the metal wires 25. The glass substrate 10 includes the detection electrodes 120 that detect electrostatic capacitance. This configuration prevents current flow between the wire body 253 and the glass substrate 10, even when the wire body 253 of the metal wire 25 is in contact with the glass substrate 10.

The detection element 50 according to the first embodiment allows a loop height of the metal wire 25 to be lower than that in a comparative example described later (refer to FIG. 23), thereby making it possible to reduce a thickness d1 (refer to FIG. 6) of the resin member 33 above the glass substrate 10. The thickness d1 is a distance between the upper surface 10a of the glass substrate 10 and the upper surface 33a of the resin member 33. The reduction in the thickness d1 can reduce a distance between the finger Fin in contact with the upper surface 33a of the resin member 33 and the detection electrode 120. The shorter the distance between the finger Fin and the detection electrode 120, the higher the detection sensitivity of the finger print by the detection element 50. As a result, the detection device 100 capable of increasing the detection sensitivity can be provided.

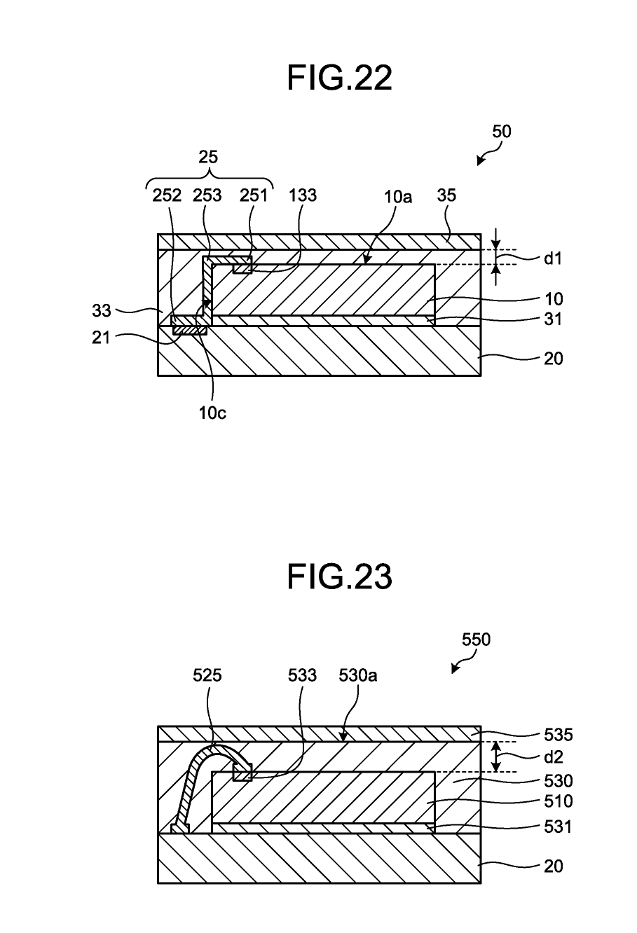

FIG. 22 is a cross-sectional view illustrating a state where the metal wire is in contact with the glass substrate in the detection element according to the first embodiment. The wire body 253 may be in contact with at least one of the upper surface 10a and the side surface 10c of the glass substrate 10. The wire body 253 may extend in parallel with at least one of the upper surface 10a and the side surface 10c of the glass substrate 10. As exemplarily illustrated in FIG. 22, the wire body 253 may be in contact with both the upper surface 10a and the side surface 10c of the glass substrate 10. The wire body 253 may be in contact with a corner between the upper surface 10a and the side surface 10c of the glass substrate 10. One part of the wire body 253 may extend in parallel with the upper surface 10a of the glass substrate 10 and the other part of the wire body 253 may extend in parallel with the side surface 10c of the glass substrate 10. These aspects can further reduce the loop height of the metal wire 25, thereby making it possible to further reduce the thickness d1. This can further increase the detection sensitivity of the detection element 50.

The base material 101 made of glass is cheaper than a semiconductor base material such as silicon. This can reduce manufacturing costs of the detection element 50 and the detection device 100 including the detection element 50.

The detection device 100 according to the first embodiment includes the detection element 50, the second circuit substrate 60, and the transmission conductor 70. The second circuit substrate 60 is positioned close to the lower surface 20b of the first circuit substrate 20 included in the detection element 50. The transmission conductor 70 is attached to the second circuit substrate 60 and adjacent to the resin member 33. With this configuration, the detection device 100 can transmit the drive signal Vs output from the detection controller 11 to the finger Fin via the transmission conductor 70, when the finger Fin is in contact with or in proximity to the resin member 33.

The transmission conductor 70 has the first portion 71 adjacent to the side surface 33c of the resin member 33, and the second portion 72 that is supported by the first portion 71 and covers the upper surface 33a of the resin member 33. The second portion 72 is provided with the through-hole 70H at a position facing the glass substrate 10. Accordingly, the second portion 72 serves as a ring surrounding a space above the glass substrate 10. This configuration makes it easy to cause the finger Fin to be in contact with the transmission conductor 70, when the finger Fin is in contact with or in proximity to the finger print sensor 1 as illustrated in FIG. 13.

The first circuit substrate 20 is a rigid substrate such as a PCB. The second circuit substrate 60 is a flexible substrate. The first circuit substrate 20 having a high strength makes it easy to bond the second end portion 252 of the metal wire 25 to the first circuit substrate 20 using a wire bonding device. The second circuit substrate 60 is bendable. This configuration allows the second circuit substrate 60 to be easily housed in a non-illustrated housing of an electronic apparatus, thereby making it possible to increase a degree of freedom in attaching the detection device 100 to the electronic apparatus.

In the first embodiment, the detection device 100 detects the shape and the finger print of the finger Fin, as described above. A detection target by the detection device 100 is not limited to the finger Fin, and may be a palm instead of the finger Fin. The detection target by the detection device 100 may be both the finger Fin and a palm. The detection device can detect the shape of a palm and a palm print by detecting a change in capacitance caused by ridges and valleys of the palm.

In the first embodiment, the transmission conductor 70 has the first portion 71 and the second portion 72, and the second portion 72 is provided with the through-hole 70H, as described above. The configuration of the transmission conductor 70 is not limited to the configuration of the first embodiment. The second portion 72 may be provided with a notch (not illustrated), instead of the through-hole 70H, at the position facing the glass substrate 10. Alternatively, the transmission conductor 70 may only have the first portion 71. Even according to this aspect, the finger Fin can be in contact with the transmission conductor 70 when the finger Fin is in contact with or in proximity to the finger print sensor 1.

While the metal wires 25 are used in the first embodiment, a conductive paste may be used instead of the metal wires 25. The conductive paste can be disposed along the upper surface 10a and the side surface 10c of the glass substrate 10, instead of the metallic wire 25 illustrated in FIG. 6. This configuration can couple the pad electrode 133 provided on the glass substrate to the pad electrode 21 on the first circuit substrate 20 by the conductive paste.

### COMPARATIVE EXAMPLE

FIG. 23 is a cross-sectional view illustrating an exemplary configuration of a detection element according to a comparative example. As illustrated in FIG. 23, a detection element 550 according to the comparative example includes the first circuit substrate 20, a silicon substrate 510, a metal wire 525, a resin member 530, and a coating layer 535. The silicon substrate 510 is provided above the first circuit substrate 20 with an adhesive layer 531 interposed therebetween. The metal wire 525 couples a pad electrode 533 on the silicon substrate 510 to the first circuit substrate 20. The resin member 530 covers the silicon substrate 510 and the metal wire 525. The coating layer 535 is provided on an upper surface 530a of the resin member 530. In the detection element 550 according to the comparative example, when the metal wire 525 is in contact with an edge portion or a side surface of the silicon substrate 510, current may flow between the metal wire 525 and the silicon substrate 510. Accordingly, the metal wire 525 is formed to have a high loop height so as not to be in contact with the edge portion or the side surface of the silicon substrate 510. Forming the metal wire 525 to have a high loop height causes the resin member 530 to be formed thick. As a result, a thickness d2 of the resin member 530 above the silicon substrate 510 is thicker than the thickness d1 (refer to FIGS. 6 and 22) in the first embodiment.

### Second Embodiment

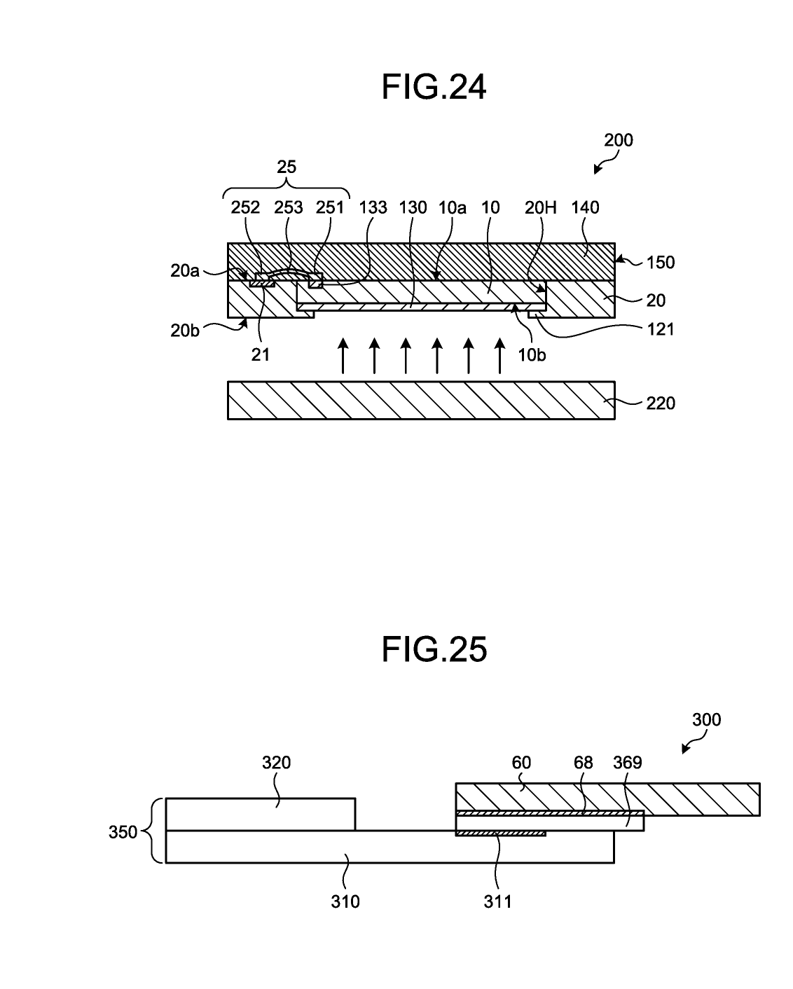

FIG. 24 is a cross-sectional view illustrating an exemplary configuration of a detection device according to a second embodiment. As illustrated in FIG. 24, a detection device 200 according to the second embodiment includes a detection element 150 and an optical sensor 220. The detection element 150 includes the glass substrate 10, the metal wire 25, the first circuit substrate 20, an adhesive sheet 130 having a light transmitting property, and a resin member 140 having a light transmitting property.

In the second embodiment, the first circuit substrate 20 is provided with a through-hole 20H. The through-hole 20H passes from the upper surface 20a to the lower surface 20b of the first circuit substrate 20. The inner circumferential surface of the through-hole 20H on the lower surface 20b side of the first circuit substrate 20 has an edge portion 121 protruding toward the center of the through-hole 20H. Accordingly, a diameter of the through-hole 20H on the lower surface 20b side is smaller than that on the upper surface 20a side of the first circuit substrate 20.

The adhesive sheet 130 having a light transmitting property is pasted on the lower surface 10b of the glass substrate 10. The glass substrate 10 is disposed in the through-hole 20H of the first circuit substrate 20 in such a state that the lower surface 10b on which the adhesive sheet 130 is pasted faces downward. The peripheral edge portion of the glass substrate 10 is fixed to the edge portion 121 with the adhesive sheet 130 interposed therebetween.

The metal wire 25 couples the pad electrode 133 on the glass substrate 10 in the through-hole 20H to the pad electrode 21 on the first circuit substrate 20. The resin member 140 having a light transmitting property covers the upper surface 10a of the glass substrate 10, the upper surface 20a of the first circuit substrate 20, and the metal wire 25.

The optical sensor 220 faces the glass substrate 10 with the adhesive sheet 13 having a light transmitting property interposed therebetween. The optical sensor 220 monitors the resin member 140 through the glass substrate 10 in the through-hole 20H. When detecting the finger Fin in contact with or in proximity to the resin member 140, the optical sensor 220 emits light. A user can know that the detection device 200 has detected the finger Fin by visually recognizing light emitted from the optical sensor 220.

As described above, the detection device 200 according to the second embodiment includes the detection element 150 and the optical sensor 220. The detection element 150 includes the first circuit substrate 20, the glass substrate 10, the metal wires 25, and the resin member 140. The glass substrate 10 is attached to the upper surface 20a of the first circuit substrate 20. The metal wires 25 each couple the pad electrode 21 on the upper surface 20a of the first circuit substrate 20 to the corresponding pad electrode 133 on the glass substrate 10. The resin member 140 covers the glass substrate 10 and the metal wires 25. The glass substrate 10 includes the detection electrodes 120 that detect electrostatic capacitance. With this configuration, the detection element 150 can also reduce the loop heights of the metal wires 25 and the thickness of the resin member 140. As a result, the detection device 200 capable of increasing the detection sensitivity can be provided.

### Third Embodiment

FIG. 25 is a schematic diagram illustrating an exemplary configuration of an electronic apparatus according to a third embodiment. As illustrated in FIG. 25, an electronic apparatus 300 according to the third embodiment includes the detection device 100 (not illustrated) described in the first embodiment and a liquid crystal display 350 coupled to the detection device 100, for example. The liquid crystal display 350 includes a thin film transistor (TFT) substrate 310, a counter substrate 320, and a liquid crystal layer (not illustrated). Thin film transistors (TFTs) and the like are formed on the TFT substrate 310. The liquid crystal layer is disposed between the TFT substrate 310 and the counter substrate 320. In this example, the TFT substrate 310 includes pad electrodes 311. The pad electrode 311 is coupled to a pad electrode 68 on the second circuit substrate 60 with an ACF 369 interposed therebetween. With this configuration, the electronic apparatus 300 with a detection function can transmit a detection result, such as a finger print, by the detection device 100 to the liquid crystal display 350. The electronic apparatus 300 can turn on or off a power source of the liquid crystal display 350 based on a detection result, such as a finger print, by the detection device 100, and display the detection result on the liquid crystal display 350.

As described above, the electronic apparatus 300 according to the third embodiment includes the detection device 100. The detection device 100 includes the detection element 50 having the metal wires 25 having a low loop height. As a result, the electronic apparatus 300 capable of increasing the detection sensitivity can be provided.

In the third embodiment, the liquid crystal display 350 is coupled to the detection device, as described above. The device to be coupled to the detection device is not limited to the liquid crystal display, and may be an organic electro luminescence (EL) display.

While exemplary embodiments according to the present disclosure have been described, the embodiments are not intended to limit the present disclosure. The contents disclosed in the embodiments are given by way of example only, and various changes may be made without departing from the spirit of the present disclosure. Appropriate changes made without departing from the spirit of the present disclosure naturally fall within the technical scope of the present disclosure.

The detection device and the electronic apparatus according to the present disclosure can include the following aspects, for example.
(1) A detection device, comprising:

a first circuit substrate;

a glass substrate attached at a position close to one surface of the first circuit substrate;

a metal wire that couples an electrode provided on the one surface of the first circuit substrate to an electrode provided on the glass substrate; and

a resin member that covers the glass substrate and the metal wire, wherein

the glass substrate includes a detection electrode that detects electrostatic capacitance.
(2) The detection device according to (1), wherein

the glass substrate includes:
a first surface facing the first circuit substrate;
a second surface that is an opposite side of the first surface; and
a third surface positioned between the first surface and the second surface,

the metal wire includes:
a wire body:
a first end portion positioned at one end of the wire body and bonded to the second surface of the glass substrate; and
a second end portion positioned at the other end of the wire body and bonded to the first circuit substrate, and

the wire body is in contact with at least one of the second surface and the third surface of the glass substrate.
(3) The detection device according to (2), wherein the wire body extends in parallel with at least one of the second surface and the third surface of the glass substrate.
(4) The detection device according to any one of (1) to (3), further comprising:

a second circuit substrate positioned close to another surface, which is an opposite side of the one surface, of the first circuit substrate; and

a transmission conductor attached to the second circuit substrate, wherein

the transmission conductor is adjacent to the resin member.
(5) The detection device according to (4), wherein

the transmission conductor includes:
a first portion adjacent to a side surface of the resin member; and
a second portion that is supported by the first portion and covers an upper surface of the resin member, and

the second portion is provided with a through-hole at a position facing the glass substrate.
(6) The detection device according to (4) or (5), wherein

the first circuit substrate is a rigid substrate, and

the second circuit substrate is a flexible substrate.
(7) An electronic apparatus, comprising:

a detection device; and

a device that is coupled to the detection device, wherein

the detection device includes:
a first circuit substrate;
a glass substrate attached to the first circuit substrate;
a metal wire that couples an electrode provided on the first circuit substrate to an electrode provided on the glass substrate; and
a resin member that covers the glass substrate and the metal wire, and

the glass substrate includes a detection electrode that detects electrostatic capacitance.
(8) The electronic apparatus according to (7), wherein

the glass substrate includes:
a first surface facing the first circuit substrate;
a second surface that is an opposite side of the first surface; and
a third surface positioned between the first surface and the second surface, and

the metal wire includes:
a wire body:
a first end portion positioned at one end of the wire body and coupled to the second surface of the glass substrate; and
a second end portion positioned at the other end of the wire body and bonded to the first circuit substrate, and

the wire body is in contact with at least one of the second surface and the third surface of the glass substrate.
(9) The electronic apparatus according to (8), wherein the wire body extends in parallel with at least one of the second surface and the third surface of the glass substrate.
(10) The electronic apparatus according to any one of (7) to (9), further comprising:

a second circuit substrate that is positioned close to another surface, which is an opposite side of the one surface, of the first circuit substrate; and

a transmission conductor attached to the second circuit substrate, wherein

the transmission conductor is adjacent to the resin member.
(11) The electronic apparatus according to (10), wherein

the transmission conductor includes:
a first portion adjacent to a side surface of the resin member; and
a second portion that is supported by the first portion and covers an upper surface of the resin member, and

the second portion is provided with a through-hole at a position facing the glass substrate.
(12) The electronic apparatus according to (10) or (11),
   wherein the first circuit substrate is a rigid substrate, and the second circuit substrate is a flexible substrate.

What is claimed is:

1. A detection device, comprising:
a first circuit substrate;
a glass substrate attached at a position close to one surface of the first circuit substrate;
a metal wire that couples an electrode provided on the one surface of the first circuit substrate to an electrode provided on the glass substrate; and
a resin member that covers the glass substrate and the metal wire, wherein
the glass substrate includes a detection electrode that detects electrostatic capacitance.

2. The detection device according to claim 1, wherein
the glass substrate includes:
a first surface facing the first circuit substrate;
a second surface that is an opposite side of the first surface; and
a third surface positioned between the first surface and the second surface, the metal wire includes:
a wire body:
a first end portion positioned at one end of the wire body and bonded to the second surface of the glass substrate; and
a second end portion positioned at the other end of the wire body and bonded to the first circuit substrate, and
the wire body is in contact with at least one of the second surface and the third surface of the glass substrate.

3. The detection device according to claim 2, wherein the wire body extends in parallel with at least one of the second surface and the third surface of the glass substrate.

4. The detection device according to claim 1, further comprising:
a second circuit substrate positioned close to another surface, which is an opposite side of the one surface, of the first circuit substrate; and
a transmission conductor attached to the second circuit substrate, wherein
the transmission conductor is adjacent to the resin member.

5. The detection device according to claim 4, wherein
the transmission conductor includes:
a first portion adjacent to a side surface of the resin member; and
a second portion that is supported by the first portion and covers an upper surface of the resin member, and
the second portion is provided with a through-hole at a position facing the glass substrate.

6. The detection device according to claim 4, wherein
the first circuit substrate is a rigid substrate, and
the second circuit substrate is a flexible substrate.

7. An electronic apparatus, comprising:
a detection device; and
a device that is coupled to the detection device, wherein
the detection device includes:
a first circuit substrate;
a glass substrate attached to the first circuit substrate;
a metal wire that couples an electrode provided on the first circuit substrate to an electrode provided on the glass substrate; and
a resin member that covers the glass substrate and the metal wire, and
the glass substrate includes a detection electrode that detects electrostatic capacitance.

8. The electronic apparatus according to claim 7, wherein
the glass substrate includes:
a first surface facing the first circuit substrate;
a second surface that is an opposite side of the first surface; and
a third surface positioned between the first surface and the second surface, and
the metal wire includes:
a wire body:
a first end portion positioned at one end of the wire body and coupled to the second surface of the glass substrate; and
a second end portion positioned at the other end of the wire body and bonded to the first circuit substrate, and
the wire body is in contact with at least one of the second surface and the third surface of the glass substrate.

9. The electronic apparatus according to claim 8, wherein the wire body extends in parallel with at least one of the second surface and the third surface of the glass substrate.

10. The electronic apparatus according to claim 7, further comprising:
a second circuit substrate that is positioned close to another surface, which is an opposite side of the one surface, of the first circuit substrate; and
a transmission conductor attached to the second circuit substrate, wherein
the transmission conductor is adjacent to the resin member.

11. The electronic apparatus according to claim 10, wherein
the transmission conductor includes:
a first portion adjacent to a side surface of the resin member; and
a second portion that is supported by the first portion and covers an upper surface of the resin member, and
the second portion is provided with a through-hole at a position facing the glass substrate.

12. The electronic apparatus according to claim 10, wherein the first circuit substrate is a rigid substrate, and the second circuit substrate is a flexible substrate.
